(19) United States
(12) Patent Application Publication
(10) Pub. No.: US 2012/0325290 A1
(43) Pub. Date: Dec. 27, 2012

(54) SOLAR COGENERATION VESSEL

(75) Inventor: ANDREW ROMAN GIZARA, LAKE FOREST, CA (US)

(73) Assignee: INTEGRATED POWER TECHNOLOGY CORPORATION, Lake Forest, CA (US)

(21) Appl. No.: 13/169,236

(22) Filed: Jun. 27, 2011

(51) Int. Cl. H01L 31/058; F24J 2/38; G06F 17/00; F24J 2/04

(52) U.S. Cl. 136/248; 126/634; 126/600; 701/21

(57) ABSTRACT

An offshore vessel embodies a mobile buoyant energy recovery system enabled to extract energy from solar power. An exemplary energy recovery system comprises concentrating solar thermal power systems (CSP) or concentrating photovoltaic power (CPV) systems on the deck of the vessel. Within the vessel hull, ballast water serves multiple purposes. The ballast not only stabilizes the vessel, but also provides reactant for hydrogen electrolysis or ammonia synthesis, or steam for a turbine. For CPV systems the ballast conducts heat as a coolant improving the efficiency and durability of photovoltaic cells. For CSP systems the ballast water becomes superheated steam through a primary heat exchanger in the concentrator. In some embodiments, some steam from the CSP primary heat exchanger or from the CPV coolant system undergoes high-pressure electrolysis of enhanced efficiency due to its high temperature. In some embodiments, the remaining steam that did not undergo electrolysis drives a steam turbine providing electrical current for electrolysis. A secondary heat exchanger takes heat from the steam expelled from an energy storage process to efficiently distill ballast water at a lower temperature thus minimizing corrosion and build-up of scale. A remote control Supervisory Control and Data Acquisition System (SCADA) determines position, navigation, configuration, and operation of the preferably unmanned modular mobile buoyant energy recovery structure based on Geospatial Information Systems (GIS), Velocity Performance Prediction (VPP) models, Global Positioning Satellites (GPS) and various onboard sensors and controls.

### BACKGROUND OF THE INVENTION

1. Field of the Invention

The present invention is generally in the field of power cogeneration systems. More specifically, the present invention teaches a remote-controlled modular mobile buoyant solar cogeneration plant that optimally recovers and delivers energy from an offshore marine environment.

2. Background Art

Today while worldwide investment in solar power systems reaches ever-increasing proportions, technology has not addressed many physical and regulatory constraints that impede rapid deployment of utility-scale systems. The solar power system manufacturing industry now in its nascent stages risks overcapacity and subsequent consolidation despite energy demand actually increasing, unless technology soon enables rapid deployment.

With the output of renewable energy systems primarily utilizing electrical current as the energy carrier, the existing electrical grid must accommodate an increase of capacity afforded by new deployments. Both terrestrial wind and solar power proposed installations must competitively bid for access to limited transmission of power on what operators refer to as an oversubscribed grid. In such circumstances the grid operator and the energy system developer must negotiate shared costs in upgrading the grid near the energy resource.

The intermittency of renewable resources such as wind and solar has increased costs and instigates their systems' inherent inability to load-balance that leads to curtailment. For instance, idling wind turbines when available power exceeds demand effectively increases the price per Watt generated due to fixed operations and maintenance costs. While energy storage theoretically alleviates these difficulties, the storage system cost and the round trip efficiency of storing and retrieving the stored energy in batteries or hydrogen electrolyzers and fuel cells render these systems uneconomical. Also, other physical and technological constraints to extant storage systems include: limited availability of battery materials and suitable non-toxic chemistry; co-location of storage with the resource which does not circumvent the aforementioned oversubscribed grid requiring upgrade; and often, developers must deploy especially solar power generation plants where water resources for steam turbine electrical generation or hydrogen electrolysis bear critical scarcity.

As human population grows, the value of arable land increases putting further constraints on rapid deployment of solar plants, as laws already exist to protect farmland adding further regulatory delay in renewable energy development and installation. Renewable energy system developers have commonly faced further regulatory delay due to unique electrical codes required by each locality of installations, and especially due to proposed installations threatening protected or endangered wildlife species and causing aesthetic objections raised by local human residents.

Therefore, there exists a need for a novel solar energy recovery system that most efficiently provides energy from natural resources when and where available and needed while overcoming regulatory, technological, and physical constraints inherent in the existing energy infrastructure to facilitate rapid deployment of extant solar power systems.

### SUMMARY OF THE INVENTION

The present invention is directed to a novel remote-controlled mobile buoyant energy recovery system that recovers and delivers solar energy from offshore. The present invention teaches an offshore energy recovery and delivery system as a means to overcome regulatory land use restrictions, water scarcity, resource intermittency, existing grid capacity and load-balancing limitations, and to reduce costs and improve efficiency to promote rapid development of resources. Through novel cogeneration techniques, the present invention optimally utilizes natural resources by most efficiently generating power and storing energy thus enabling solar power to fulfill a baseload power generation as well as a hydrogen fuel niche.

Intrinsic to all solar power systems, power generation incurs energy in the form of heat where management of this heat fundamentally affects overall efficiency of the generation system. Concentrating Solar Thermal Power (CSP) systems primarily generate heat to drive a heat engine or to flash steam for a turbine; either a turbine or an engine then converts mechanical energy to electrical power by coupling to a generator. This yields relatively low, no greater than about forty per cent, efficiency conversion of solar power to electrical power.

Concentrating Photovoltaic (CPV) systems suffer deleterious effects from heat generation. Because photovoltaic cells operate under the principle of photons bombarding a semiconductor therein liberating electrons, and electron mobility diminishes inversely proportional to temperature, heat reduces the power efficiency of photovoltaic cells. Furthermore, based on Weibull survivability models, increases in substrate temperature may exponentially shorten the durability of photovoltaic cells for a given set of environmental conditions.

Thus, the present invention elucidates heat management techniques for both CSP and CPV systems that enhance efficiency in both systems, improves durability of CPV, and substantially enhances efficiency of energy storage by performing hydrogen electrolysis or ammonia synthesis on high temperature water used to manage the heat in the CSP or CPV system. For instance, while extant polymer electrolyte membrane (PEM) hydrogen electrolyzers have practical electrical power-to-hydrogen conversion efficiencies of seventy to eighty per cent using water at standard pressure and temperature, high temperature and pressure steam solid oxide electrolysis cells (SOEC) have reported conversion efficiencies above ninety per cent. Likewise, liquefied ammonia as an energy carrier possesses a greater volumetric energy density based on concentration of hydrogen atoms compared to liquid hydrogen itself Given the electrical power to hydrogen storage efficiency improvement of the present invention, round-trip energy storage and retrieval based on existing hydrogen fuel cells gains approximately ten per cent efficiency in absolute terms, thus enabling cost-competitive baseload functionality, load-balancing and energy delivery transcending common regulatory obstructions.

The abundance of this heat when properly managed as disclosed herein not only efficiently generates power and efficiently stores energy, but also most efficiently allows refining of raw feedstock, namely desalinating seawater, for hydrogen electrolysis or ammonia synthesis based storage. Thus, the present invention introduces a novel configuration of power generation and energy storage of utmost efficiency while solving feedstock scarcity issues inhibiting rapid deployment of especially CSP systems.

This present specification herein incorporates by reference U.S. Pat. No. 7,698,024 and its continuation U.S. patent application Ser. No. 13/073,891 entitled: SUPERVISORY CONTROL AND DATA ACQUISITION SYSTEM FOR ENERGY EXTRACTING VESSEL NAVIGATION. The invention incorporated by reference applies to remote control of any mobile system that exploits energy from weather patterns that avail formidable amounts of naturally occurring energy. The referenced invention exemplifies an offshore energy recovery system wherein an algorithm optimizes efficiency in the system by accounting for data from weather observations, and from sensors on the mobile structure, while relating these data points to performance models for the mobile structure itself. Its Supervisory Control And Data Acquisition (SCADA) computer servers run Human Machine Interface (HMI) secure software applications which communicate to microprocessor systems running client software with a Graphical User Interface (GUI) to allow remote humans to optionally interact and choose mission critical navigation plans. Any mobile structure that extracts energy from offshore weather patterns for renewable energy recovery under remote control, including an embodiment of the present invention, especially benefits from the invention herein incorporated by reference. Specifically, the system embodied within the U.S. Pat. No. 7,698,024 and its continuation patent application Ser. No. 13/073,891 herein incorporated by reference comprises an algorithm that optimizes energy extraction using yield functions derived from weather and geospatial data and vessel performance models. Thus an embodiment of the present invention benefits from the patent and its continuation patent application herein incorporated by reference by using the path cost algorithm weighing energy extraction yield factors into the cost of travel to guide navigation of vessels for solar power generation embodying the present invention navigated by remote control for optimal solar power recovery and delivery away from overcast weather patterns thereby averting conditions that exacerbate intermittency.

The present invention reduces the Levelized Cost Of Energy (LCOE) typically associated with solar power systems by primarily eliminating cost of land use in the form of both land lease agreements, and unpredictable up-front regulatory compliance costs such as environmental impact studies. Similarly, the present invention minimizes another factor in the Levelized Cost of Energy (LCOE) calculation that arises from maintenance and operations cost. Because under all cases less severe than catastrophic failure, a mobile structure can always return to a central service facility co-located with distribution where a small crew performs maintenance procedures in an assembly line manner as opposed to a more costly field crew working in potentially harsh environments. Also during the process of energy delivery itself, the mobile structure can continue to extract and store energy from the environment, substantially enhancing overall system energy production.

As an extension of the U.S. Pat. No. 7,698,024 and its continuation patent application Ser. No. 13/073,891 herein incorporated by reference, an addition to the SCADA server side applications which access a Geographic Information System (GIS) may also comprise a database that records resource local spot prices and calculates Levelized Cost of Energy (LCOE), a variable in a risk/reward evaluation function based on human demand for various commodity products potentially output from an embodiment of the present invention such as pure hydrogen compressed or stored in a hydride; electrical energy in a charged battery; pure oxygen; liquefied ammonia; or desalinated water. Such a function to assess risk/reward facilitates optimal modular response to weather and local spot market conditions, favorably affecting equitable distribution of energy and energy-intensive resources to humankind.

Therefore, the present invention facilitates the CSP or CPV developer to rapidly deploy offshore their systems in an embodiment of the present invention thereby overcoming the aforementioned limitations of land use restrictions and water scarcity while mitigating resource intermittency risks and mitigating oversubscribed grid risk and grid upgrade costs by navigating to clear weather patterns and by efficiently delivering stored energy to grid or fuel or resource distribution locations closer to densely populated areas where demanded.

### BRIEF DESCRIPTION OF THE DRAWINGS

FIG. 1 illustrates a view of an exemplary concentrating solar thermal power (CSP) system in accordance with one embodiment of the present invention.

FIG. 2 illustrates a view of an exemplary concentrating photovoltaic (CPV) system in accordance with one embodiment of the present invention.

FIG. 3 illustrates a view of an exemplary CSP and wind cogeneration system in accordance with one embodiment of the present invention.

FIG. 4 illustrates a view of an exemplary system utilizing ammonia synthesis energy storage in accordance with one embodiment of the present invention.

### DETAILED DESCRIPTION OF THE INVENTION

The present invention pertains to a mobile buoyant energy recovery system featuring novel solar heat management that ensures highly efficient energy storage and abundant feedstock in combination with a remote control system and algorithm for supervisory control and data acquisition enabling optimal configuration, navigation and autonomous operation of the system. The following description contains specific information pertaining to various embodiments and implementations of the invention. One skilled in the art will recognize that one may practice the present invention in a manner different from that specifically depicted in the present specification. Furthermore, the present specification need not represent some of the specific details of the present invention in order to not obscure the invention. A person of ordinary skill in the art would have knowledge of such specific details not described in the present specification. Others may omit or only partially implement some features of the present invention and remain well within the scope and spirit of the present invention.

The following drawings and their accompanying detailed description apply as merely exemplary and not restrictive embodiments of the invention. To maintain brevity, the present specification has not exhaustively described all other embodiments of the invention that use the principles of the present invention and has not exhaustively illustrated all other embodiments in the present drawings.

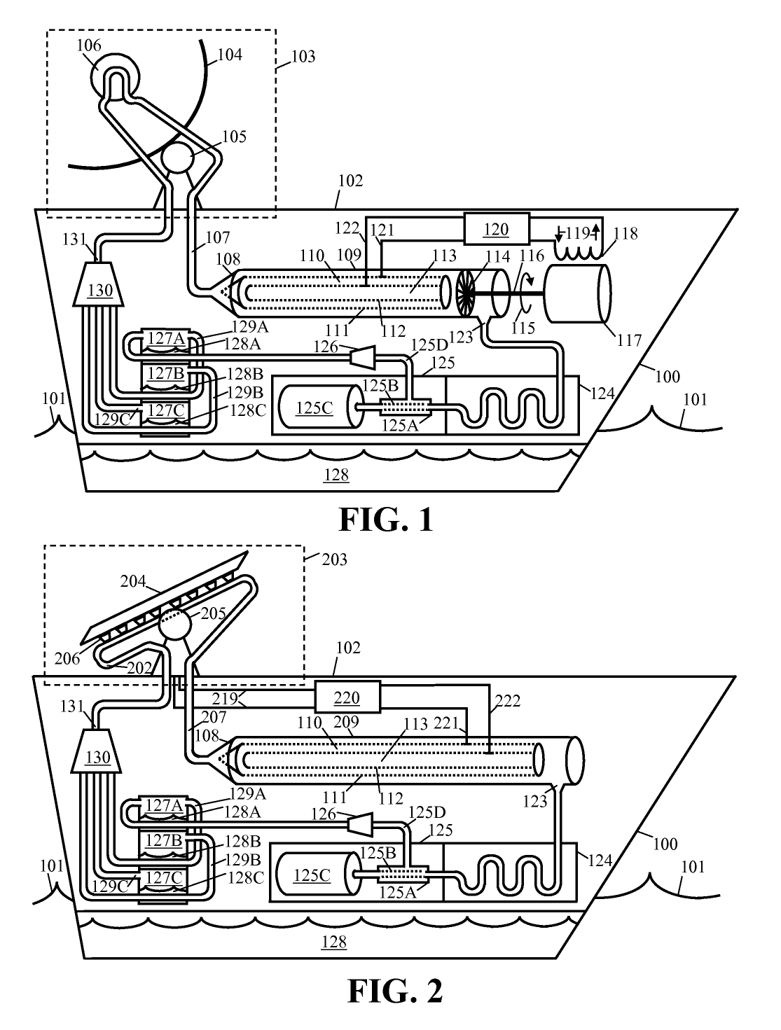

FIG. 1 illustrates an exemplary practical embodiment of a concentrating solar thermal power (CSP) system within the scope of the present invention. The vessel outline 100 represents an offshore mobile energy recovery structure in the process of energy extraction and/or energy delivery in an exemplary embodiment of the present invention. Exemplary embodiments of mobile structure 100 for the present invention include sailing or propelled vessels or barges or any mobile buoyant energy recovery system comprising any solar powered energy conversion system known by one of ordinary skill in the art. While FIG. 1 depicts a CSP system 103, subsequently FIG. 2 illustrates a concentrating photovoltaic (CPV) system 203 and one must understand any combination of CSP 103 and CPV 203 energy conversion systems or hybrid systems thereof remain within the scope of the present invention. For instance a system that separates and focuses infrared spectrum sunlight for concentrating thermal energy while elsewhere the same apparatus focuses the visible through ultraviolet spectrum for photovoltaic operation remains an exemplary solar energy extracting system within the scope of the present invention. For the purposes of the present specification of exemplary embodiments of CSP 103, while this specification primarily describes solar energy converters that employ high temperature electrolysis 109, 209, 309 as means of hydrogen and oxygen production, a unit 103 that performs thermolysis; catalytic thermolysis; or bio-fuel production with any fuel or raw material as a commodity product with heat as a byproduct, remains within the scope and spirit of the present invention. The aforementioned solar energy converters embodied in mobile buoyant energy systems 100 represent purely exemplary embodiments by no means restrictive of solar energy converters in mobile buoyant energy system 100 embodiments within the scope and spirit of the present invention.

FIG. 1 further depicts mobile structure 100 in the process of energy extraction and/or energy delivery navigating an offshore environment 101. Note that this representation of an offshore environment 101 is strictly exemplary and that an offshore environment 101 consistent with a description of an ocean; a sea; a lake; a bay; a sound; a channel; a strait; a river; a delta, an estuary, or any large body of fresh, salt, or brackish water, remains well within the scope of an offshore environment 101 for the purposes of the present invention. The exemplary embodiment further comprises a deck 102 for the purpose of mounting one or plural energy conversion devices of similar class, or different classes co-operating in a cogeneration scheme. Particularly upon the deck 102 the CSP 103 or a CPV 203 of the mobile structure 100 extracts heat energy from solar power.

As previously introduced, FIG. 1 illustrates a CSP system 103 mounted on the deck 102 of the mobile structure 100. The present specification makes no restriction as to the configuration of the CSP system 103 for any embodiment of the present invention. For instance, the reflector 104 surface of FIG. 1 resembles the cross section of a parabolic trough or parabolic dish that reflects sunlight onto a focal point or thermal concentrator 106 centered above the reflector 104, although a tower-type thermal concentrator 106 centered in the midst of an array of planar reflectors would remain within the scope of the present invention. The solar tracking mounting 105 functions to track the position of the sun and accordingly adjust the position of the reflector 104 to ensure a maximum amount of solar energy reaches the concentrator 106. As the entire CSP system 103 mounts on, or in severe weather below, the deck 102 of a mobile structure 100 offshore 101, the algorithm that controls the solar tracking of the reflector 104 by the mounting 105 must take into account and average the periodic displacement of the deck 102 relative to true horizon due to wave motion offshore 101. To achieve the desired results, the vessel 100 will have inertial displacement sensors such as accelerometers and gyroscopes, and time referenced Global Position Satellite (GPS) tracking, which the vessel's 100 supervisory control and data acquisition (SCADA) system polls by sampling the data from said inertial displacement sensors and GPS to determine the position in which the mounting 105 sets the reflector 104. One efficiency improving, cost reducing function that the SCADA system can implement is to moor or set the heading of the vessel 100 in an orientation relative to the equator of the earth to allow simpler one axis solar tracking for the reflector 104 and its mounting 105. The SCADA system can also implement cleansing the reflector 104 using water or steam from anywhere in the system 100 to enhance CSP 103 performance based on data object tags describing a maintenance schedule database. All these data input to the SCADA system which includes GPS inputs also includes wind and cloud coverage weather prediction to determine best longitude and latitude to place the CSP 103 and to thoroughly map navigational routes based on Velocity Performance Prediction (VPP) and path cost and total yield analysis of the vessel 100 as taught by herein incorporated by reference U.S. Pat. No. 7,698,024 and its continuation U.S. patent application Ser. No. 13/073,891 entitled: SUPERVISORY CONTROL AND DATA ACQUISITION SYSTEM FOR ENERGY EXTRACTING VESSEL NAVIGATION. As an extension of the U.S. Pat. No. 7,698,024 and its continuation patent application Ser. No. 13/073,891 herein incorporated by reference, an addition to the SCADA server side applications which access a Geographic Information System (GIS) may also comprise a database recording resource local spot prices and calculating Levelized Cost of Energy (LCOE) reflecting a risk/reward total analysis taking into consideration the variety of CSP 103 and energy and commodity resource storage options availed by a modular mobile buoyant energy recovery system 100, and global commodity local spot prices and future prices into the path cost and total yield analysis.

For the configuration of FIG. 1, the CSP 103 comprises a heat concentrator 106 through which a primary heat exchanger flashes steam from the ballast 128 that underwent distillation through a multi-effect distiller (MED) 127A, B, C before a pump 130 forces the distilled water 131 into the heat exchanger within the concentrator 106.

For sake of simplicity and in order to not obscure the invention, the present specification omitted some valves and pumps understood necessary by one of ordinary skill in the art. For instance, as the distilled water 131 enters the heat exchanger in the concentrator 106 its temperature and pressure rapidly rises and one can assume flow and pressure control valves not shown in the drawing figures that govern the flow of the process detailed herein would comprise any reduction to practice in any embodiment of the present invention. Superheated steam exits 107 from the primary heat exchanger in the concentrator 106 at preferably 800 degrees Celsius and approximately 750 psig or about 50 bar pressure. From there it first enters a Solid Oxide Electrolyzer Cell (SOEC) 109 designed such that at the SOEC inlet 108, pressure and temperature remain constant. While FIG. 1 depicts the SOEC 109 as positioned under the deck 102 of the vessel 100, a critical design parameter, the proximity of the CSP 103 to the SOEC 109, could lead to any operating part of the CSP 103, up to the reflector 104 and heat concentrator 106 while operating, and any part of the SOEC 109 positioned above or below the deck 102. Best design practice strives to minimize the length of superheated steam conduit 107. One design feature which eliminates the conduit 107 by integrating the SOEC 109 in proximity to, or coinciding with, or within the heat concentrator and exchanger 106 remains within the scope and spirit of the present invention. Stowage under the deck 102 provides shelter from adverse environmental conditions 101. Likewise, in severe weather conditions that could cause damage to the reflector 104, every component of the CSP 103, or SOEC 109 can retract below the deck 102.

The present discussion of the construction of the SOEC 109 is purely exemplary and by no means restrictive of high temperature electrolyzer typology within the scope and spirit of the present invention. As shown in FIG. 1 the SOEC 109 appears to have an extruded cylindrical construction, and while this design may prove most economical and easy to manufacture, an SOEC 109 stack of planar design is not beyond the scope of the present invention. Also, while only one SOEC 109 may appear in the drawing figures, there exists no limitation to the scale or number of units 109 that comprise a high temperature electrolysis portion of an energy storage process embodied in a mobile buoyant energy recovery structure 100 of the present invention. For the SOEC 109 depicted in FIG. 1, the solid oxide electrolyte 110 is typically a gastight material comprised of Yttria-Stabilized Zirconia (YSZ) with a Nickel Zirconia Cermet porous cathode 111 surrounding the electrolyte 110, and a Strontium-doped Lanthanum Manganite porous anode 112 lining the inside of the electrolyte 110. Therefore, in this configuration, and with these materials in the SOEC 109, oxygen is the charge carrier, and as a voltage is applied to the anode 112 relative to the cathode 111, oxygen accumulates in the center cavity 113 of the SOEC 109, as the high pressure superheated steam that entered the SOEC 109 at the inlet 108 becomes enriched with diatomic hydrogen molecules as it traverses the length of the SOEC 109 moving towards its outlet 123. The operator of the mobile buoyant energy recovery structure 100 may compress and store the oxygen from the center cavity 113 for later distribution; or for any possible environmental 101 remediation benefiting from oxidation; or simply vent the oxygen to the surrounding environment depending upon cost and yield functions modeled by the SCADA servers informing the operator via a GUI, per the herein incorporated by reference U.S. Pat. No. 7,698,024 and its continuation U.S. patent application Ser. No. 13/073,891 entitled: SUPERVISORY CONTROL AND DATA ACQUISITION SYSTEM FOR ENERGY EXTRACTING VESSEL NAVIGATION.

As the hydrogen enriched superheated steam flows past the electrolyzer cathode 111, the aft section 123 of the SOEC 109 for the embodiment of the present invention represented in FIG. 1 also comprises a steam turbine 114. Typical steam turbine 114 operation for this application would preferably have inlet temperatures and pressures towards the upper economic practical limit of materials remaining as close as possible to the constant temperature of 800 degrees Celsius and approximately 750 psig or about 50 bar from the outlet 107 of the heat exchanger of the concentrator 106. Generally today, the upper economic practical limit of typical steam turbine 114 materials is around 540 degrees Celsius. Thus an embodiment of the SOEC 109 with an integrated steam turbine 114 that includes a heat exchanger and reservoir to store some heat for auxiliary purposes, in addition to the unit 124 shown in FIG. 1, a heat exchanger and reservoir intercepting the path of hydrogen enriched superheated steam after the SOEC 109 and before the steam turbine 114, remains within the scope of the present invention. Other embodiments that have controlled expansion of the path to cool the hydrogen enriched superheated steam after the SOEC 109 and before the steam turbine 114, also remains within the scope of the present invention. In the embodiment of FIG. 1, the steam turbine 114 operates from 800 degrees Celsius and approximately 750 psig or about 50 bar utilizing a configuration of nozzles in stages that gradually expands and cools the hydrogen enriched superheated steam flow at output 123 to a temperature and pressure dependent upon the method of hydrogen storage. The present specification describes two exemplary methods of storing hydrogen extant today, although any other method of hydrogen storage remains within the scope and spirit of the present invention.

The first exemplary method of hydrogen storage utilizes solid-state reactions in particular, a magnesium hydride tank 125C in which to store hydrogen, although utilization of other solid-state storage nanotechnology or chemistries such as lanthanum nickel is within the scope of the present invention. Because the magnesium hydride dehydrogenation endothermic reaction occurs at approximately 350 degrees Celsius at below 2 bar, a heat exchanger and reservoir 124 takes the heat from the output of the steam turbine 114 and stores this heat for other processes including possibly for dehydrogenation at a distribution site. For this purpose in this present embodiment, the heat exchanger and reservoir 124 would store the heat and circulate the heat to the hydride tank 125C during dehydrogenation using synthetic oil or other heat transfer fluid such as Therminol. Thus, for this present embodiment, the steam turbine 114 outputs hydrogen enriched superheated steam at approximately 350 degrees Celsius and less than 20 bar from which the heat exchanger and reservoir 124 takes the heat down to approximately 150 degrees Celsius and 10 bar for hydrogen storage 125. The storage unit 125 first flows the hydrogen-enriched steam at 150 degrees Celsius through a hydrogen-steam separator 125A utilizing a Nafion dryer 125B. A vacuum pump 126 draws the vaporized water 125D from the 150 degree Celsius hydrogen enriched steam flow through a Nafion dryer 125B and sends the steam 125D to a multi effect distillation (MED) unit 127A, B, C or multi stage flash distillation unit (MSF) 127A, B, C at 120 degrees Celsius. After the Nafion dryer 125B, process controls will adjust the pressure of the hydrogen between 2 to 10 bar depending upon temperature to enable the magnesium hydride tank 125C to absorb the hydrogen from the dryer 125B.

An alternative exemplary method of hydrogen storage includes compression for storage within a high pressure tank The act of compressing hydrogen gas demands greater input energy in the form of electrical power for the compressor which, while not shown in FIG. 1, would intercept the location after the Nafion dryer 125B before, for the present exemplary method of hydrogen storage embodiment, a high pressure, Type IV—non-load-bearing non-metal liner wrapped with continuous filament—tank 125C. Whereas in the previous hydrogen storage method exemplary embodiment the steam turbine 114 output hydrogen enriched steam at 350 degrees Celsius, for a compressed hydrogen gas storage method the steam turbine 114 would output hydrogen enriched steam at approximately 150 degrees Celsius and 10 bar for direct input into a hydrogen-steam separator 125A utilizing a Nafion dryer 125B, bypassing the heat exchanger and reservoir 124 for this present embodiment. The greater input to output temperature change in the steam turbine 114 necessitates a configuration of more nozzles in more stages that gradually expands and cools the hydrogen enriched superheated steam flow at output 123 to a lower temperature and pressure, thus increasing total energy output from the steam turbine 114. This increased total energy output from the steam turbine 114 will preferably upon conversion to electrical power suffice to meet the power demand of the compressor in this present embodiment. Ultimately steam turbine 114 thermal efficiency, compared to alternate energy storage methods' round trip efficiency, reliability, durability, cost, and energy density data all exist addressed by object tags in a SCADA server-side database from which the operator decides risk/reward of deploying one energy storage method over another in a modular mobile buoyant energy recovery system 100.

Regardless of which hydrogen storage method the operator chooses, the steam turbine 114 embodiment of FIG. 1 always comprises a rotor 116 that rotates 115 due to the pressure of the hydrogen enriched superheated steam impinging upon the impeller of the steam turbine 114. The rotation 115 of the rotor 116 coupled to a generator 117 in turn induces a current 119 on the armature winding 118 of the generator 117. A power regulation circuit 120 regulates voltage and current for all electrical systems on the mobile structure 100. While not shown in FIG. 1, the power regulation circuit 120 may also comprise some means of energy storage, such as a battery or a hydrogen fuel cell attached to the hydrogen storage 125C, so all electrical systems may remain functional regardless of the rotation 115 of the rotor 116. While FIG. 1 depicts the power regulation circuit 120 providing a specific voltage across the cathode 111 through the negative electrode 121 and to the anode 112 through the positive electrode 122, one may assume all electrical systems on the mobile structure 100, such as motors for pumps or compressors or solenoids for control valves, navigation or propulsion, lighting, and communications, receive their power through the power regulation circuit 120. The power regulation circuit 120 of FIG. 1 likely exists in a distributed topology, with a high voltage 119 distributed to local regulators 120 controlling low voltage processes such as electrolysis 109. Typical present day embodiments of generator 117 installed with steam turbines 114 comprise an alternating current (AC) induction generator and thus the power regulation circuit 120 may also include a power factor correction circuit to enhance the efficiency of the turbine 114 system providing alternating current electrical power 119 to transient loads 121, 122.

The power regulation circuit 120 of FIG. 1 also represents the SCADA control and communications microprocessor system per the herein incorporated by reference U.S. Pat. No. 7,698,024 and its continuation U.S. patent application Ser. No. 13/073,891 entitled: SUPERVISORY CONTROL AND DATA ACQUISITION SYSTEM FOR ENERGY EXTRACTING VESSEL NAVIGATION. In some embodiments of the present invention, the control and communications microprocessor system co-located with the power regulation circuit 120 of FIG. 1 within the mobile structure 100 comprises a type of microprocessor computing system known as a Programmable Logic Controller (PLC) by one of ordinary skill in the art of industrial process control, thus all processes on the mobile structure 100 initiate and complete and report data under control of a SCADA server side application with corresponding SCADA system control object tags through a microprocessor or PLC represented within controller 120.

The remaining functions illustrated in FIG. 1 include the process of purifying or desalinating the water from the ballast 128, which contains preferably pre-filtered water from the offshore environment 101. As previously introduced, the vacuum pump 126 separated the steam 125D through the Nafion dryer 125B from the hydrogen during the front end of the storage process, at the hydrogen-steam separator 125A. The steam 125D will exit the vacuum pump 126 at approximately 120 degrees Celsius and enter a multi effect distillation (MED) unit 127A, B, C or multi stage flash distillation unit (MSF) 127A, B, C; as one of ordinary skill in the field of distillation knows, temperatures above 120 degrees Celsius lead to more rapid corrosion or scale build-up in salt water desalination processes. As shown in FIG. 1, water vapor exits the vacuum pump 126 it enters the first stage of the MED 127A where its heat causes some of the ballast water 128A pumped from the ballast 128 to evaporate and expand. The vapor under pressure exits 129A as the brine 128A drains to the next stage 128B where the heat of the vapor 129A flashes more steam 129B. The second stage repeats the function of the previous stage as steam 129B flashes steam 129C yet again as the brine 128B drains to the third effect stage 128C. The last effect stage brine 128C may drain to the ballast 128 or environment 101, with SCADA object tags defining certain credits if applicable to environmental 101 remediation if oxygen to the environment 101, or for the cause of abating red tide or other harmful bacteria, algae, or protozoan blooms by releasing chloralkali electrolysis by-products such as lye (NaOH) or bleach (NaOCl), or sea salt concentrated saline solutions 128C from the process of distillation, to the environment 101 in selected locations, or stored back in the ballast 128 for later industrial use, and inventoried and priced accordingly with SCADA server application data object tags.

Thus, in the exemplary three stages of multi effect or multi stage flash distillation MED/MSF 127A, B, C, the temperatures of the heat conducting steam 127A, B, C vary from 120 degrees Celsius to down to 70 degrees Celsius in the final stage. While the pump 130 begins the cycle over again, it takes steam of varying temperatures and pressures from the distillation first stage 129A at above 100 degrees Celsius and above one bar or above one atmosphere pressure; from the second stage 129B at or near 100 degrees Celsius; and from the third stage 129C above 70 degrees Celsius and possibly just below one atmosphere pressure; to where these multiple flows 129A, B, C combine then exits 131 the pump 130 under pressure as a liquid again. If it fits within an energy, parts, and maintenance costs budget, reverse osmosis filtration for high purity feedstock may optionally occur here at the exit(s) 131 of the pump 130, and one may account for such modular distillation and purification design options utilizing SCADA server database application data object tags describing price, durability, maintenance cost and scheduling, yield rates, output purity in parts per million (ppm), et cetera. Be it known that the multi effect distillation process as described herein exists as purely exemplary and not in any way a restrictive embodiment of desalination or purification of water within the scope of the present invention. While the drawing figures in the present specification show three stages or effect processing tanks 127A, B, C for desalination, these drawing figures exhibit purely exemplary configurations whereby the number or scale of desalination effect or stage processing units have no implied limits. Any water purification process including reverse osmosis that benefits from vast feedstock 101 and from taking energy to purify water from any point in the heat and power processing chain 103, 109, 114, 120 in a mobile buoyant energy recovery system 100 remains within the scope of the present invention.

As previously introduced, FIG. 2 illustrates a concentrating photovoltaic CPV 203 system embodying an exemplary solar cogeneration system on a mobile buoyant energy recovery system 100 within the scope of the present invention. Equivalent to the exemplary embodiment of FIG. 1, the CPV 203 system of FIG. 2 uses purified ballast 128 water as a heat transfer fluid from the solar power conversion system 203 to the SOEC 209. In the exemplary embodiment of the present invention depicted in FIG. 2, a pump 130 forces the distilled water 131 as the coolant into the cooling system 202 for the CPV 203 system. In general, a CPV 203 system will comprise a concentrating lens 204 that focuses sunlight onto a solar photovoltaic cell at the base of the lens and cell assembly 206. In the present exemplary embodiment, the cooling fluid 131 enters the cooling system 202 through the mounting 205, conducts heat from the base of the lens and cell assembly 206 and exits the CPV 203 system through high pressure and high temperature conduit 207 to enter the SOEC 209. There exists a design trade-off mutually constrained by efficiency and durability of the solar cell improving as operating temperatures decrease while the efficiency of the SOEC 209 improves as feedstock temperature increases. Thus one designing the present system must optimize operating temperature, for instance, between 800 degrees Celsius, the preferred temperature of the feedstock for the SOEC 209, versus lowest temperature possible for the base of the lens and cell assembly 206. One design feature which eliminates the conduit 207 by integrating the SOEC 209 in proximity to, or coinciding with, or within the base of the lens and cell assembly 206 remains within the scope and spirit of the present invention. Mapping the overall system various and numerous configurations, their efficiency and durability at these various operating temperatures using data object tags in a server database application of a SCADA control system and using this data to decide configuration, operation, or navigation of the mobile buoyant energy recovery system 100 remains within the scope and spirit of the present invention.

The SOEC 209 exemplary embodiment of FIG. 2 represents a fundamental departure from the SOEC 109 exemplary embodiment of FIG. 1 due to the CPV 203 system providing electrical current to the SOEC 209, obviating the need for the steam turbine 114 in the aft section 123 of the SOEC 109 of FIG. 1. The mobile buoyant energy recovery system 100 of FIG. 2 realizes a benefit of higher efficiency hydrogen storage by integrating a CPV 203 system with an SOEC 209. Whereas a typical prior art installation of CPV 203 systems entails connection to the electric grid requiring a circuit known as an inverter to convert the direct current 219 from the CPV 203 to alternating current to the grid with surplus energy from the typical prior art installation theoretically converted to hydrogen; the present invention has the advantage of higher efficiency due to no direct current to alternating current conversion necessary with both photovoltaic generation 203 and electrolysis 209 producing and consuming direct current, 219, 221, 222 respectively, regulated 220 to corresponding voltages and currents through means such as synchronous switch mode power supply configurations substantially more efficient than inverter circuits. Thus while the CPV 203 system of FIG. 2 likely generates less heat compared to the CSP 103 system of FIG. 1, the CPV 203 system of FIG. 2 directly and perhaps more cost-effectively generates electricity as an advantage over the CSP 103 system of FIG. 1. Corresponding to FIG. 1, FIG. 2 depicts the power regulation circuit 220 providing a specific voltage across the cathode 111 through the negative electrode 221 and to the anode 112 through the positive electrode 222. One may assume all electrical systems on the mobile structure 100, such as motors for pumps or compressors or solenoids for control valves, navigation or propulsion, lighting, and communications, receive their power through the power regulation circuit 220. The power regulation circuit 220 of FIG. 2 also likely exists in a distributed topology, with a high voltage 219 distributed to local regulators 220 controlling low voltage processes such as electrolysis 209. While not shown in FIG. 2, the power regulation circuit 220 may also comprise some means of energy storage, such as a battery or a hydrogen fuel cell attached to the hydrogen storage 125C, so all electrical systems may remain functional regardless of sunlight impinging upon the CPV 203 system. The power regulation circuit 220 of FIG. 2 also represents the SCADA control and communications microprocessor system, which communicates to a central server using data object tags describing temperature, heat, electrical power, solar cell 206 maximum power point tracking control variables, and energy stored from the CPV 203 system and enables an operator to remotely track system efficiency and performance, and decide configuration, operation, or navigation of the mobile buoyant energy recovery system 100.

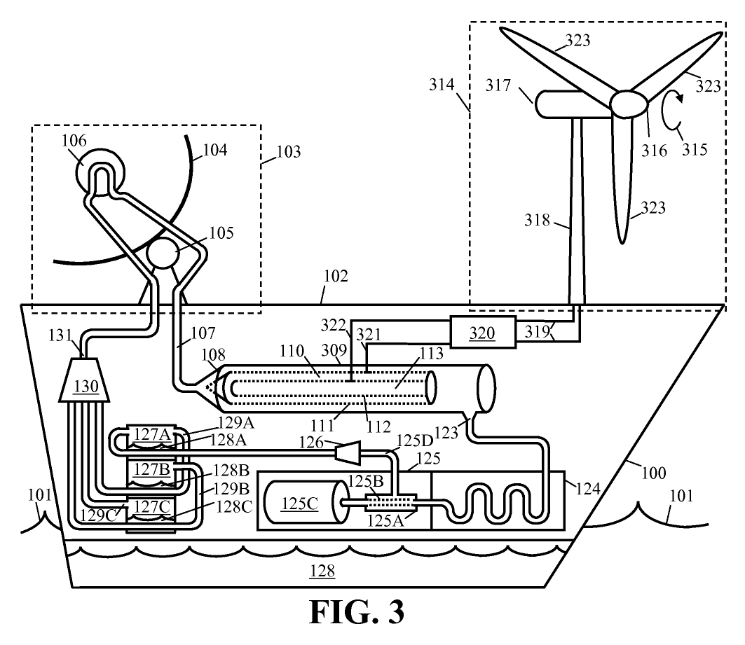

FIG. 3 presents another exemplary embodiment of a solar cogeneration system within the scope of the present invention. A CSP 103 system corresponding to that of FIG. 1 generates heat in the form of superheated steam immediately routed 107 to the SOEC 309 of FIG. 3. As before, one design feature which eliminates the conduit 107 by integrating the SOEC 309 in proximity to, or coinciding with, or within the heat concentrator and exchanger 106 remains within the scope and spirit of the present invention. The SOEC 309 of FIG. 3 exhibits a fundamental departure from the SOEC 109 exemplary embodiment of FIG. 1 due to a wind turbine 314 system in the embodiment of FIG. 3 providing electrical current to the SOEC 309, obviating the need for the steam turbine 114 in the aft section 123 of the SOEC 109 of FIG. 1. Note that while depicted in FIG. 3 as an integrated single vessel 100, a complete mobile buoyant energy recovery system 100 may exist as a single integrated unit 100, or as a mode of co-operation between separate mobile buoyant structures 100, each separately performing heat 103, and electrical 314 power generation, functioning together to produce the demanded commodity 113, 124, 125C, 128, 129A, B, C as would a singular integrated structure 100 do as depicted in FIG. 3, all remaining within the scope and spirit of the present invention. The wind turbine 314 system of FIG. 3 perhaps more cost-effectively generates electricity as an advantage over the previous solar cogeneration system embodiments of FIG. 1 and FIG. 2. Also, the heat exchanger and reservoir 124 for the embodiment of FIG. 3 can improve the overall productivity of the mobile buoyant energy recovery structure 100 by providing heat to the feedstock to the SOEC 309 when the CSP 103 does not operate, such as nighttime. However, while the wind turbine 314 system of FIG. 3 provides a least cost and high power alternative means of electricity generation while the CSP 103 converts maximum solar heat energy at least cost, the SCADA system controlling a mobile buoyant energy system 100 as configured in FIG. 3 incurs the additional burden of optimizing location and navigation of the structure 100 based on an additional environmental constraint of preferably high wind concurrent with substantially non-overcast weather conditions. Thus, the Geographic Information System (GIS) of the SCADA system controlling a mobile buoyant energy system 100 as configured in FIG. 3 provides critical weather pattern tracking and weather prediction data addressed by object tags in a SCADA server-side database from which the operator decides risk/reward of deploying one electricity generation method such as the wind turbine 314 system of FIG. 3, over another in a modular mobile buoyant energy recovery system 100.

Corresponding to FIG. 1, FIG. 3 depicts the power regulation circuit 320 providing a specific voltage across the cathode 111 through the negative electrode 321 and to the anode 112 through the positive electrode 322, one may assume all electrical systems on the mobile structure 100, such as motors for pumps or compressors or solenoids for control valves, navigation or propulsion, lighting, and communications, receive their power through the power regulation circuit 320. The power regulation circuit 320 of FIG. 3 also likely exists in a distributed topology, with a high voltage alternating current 319 distributed to local regulators 320 controlling low voltage processes such as electrolysis 309. Typical present day embodiments of generator installed within the nacelle 317 comprise an alternating current (AC) induction generator and thus the power regulation circuit 320 may also include a power factor correction circuit to enhance the efficiency of the turbine 314 system providing alternating current electrical power 319 to transient loads 321, 322. While not shown in FIG. 3, the power regulation circuit 320 may also comprise some means of energy storage, such as a battery or a hydrogen fuel cell attached to the hydrogen storage 125C, so all electrical systems may remain functional regardless of the rotation 315 of the rotor 316.

The power regulation circuit 320 of FIG. 3 also represents the SCADA control and communications microprocessor system, which communicates to a central server using data object tags describing temperature, heat, electrical power, and energy stored from the combined wind turbine 314 CSP 103 system and enables an operator to remotely track system efficiency and performance, and decide configuration, operation, or navigation of the mobile buoyant energy recovery system 100. Additional SCADA operation control object tags for the embodiment of FIG. 3 enable such mobile buoyant energy recovery structure 100 functions as: orienting the nacelle 317 such that the wind turbine 314 does not cast a shadow on the CSP 103; altering the pitch of the impeller blades 323 based on wind speed data or rotation 315 sensors; feathering the impeller blades 323 to reduce unwanted drag on the structure 100 when in transit, or to reduce risk of fatigue to the impeller blades 323 or turbine tower 318 when excessively high winds occur; utilizing the turbine tower 318 as a sailing mast for the vessel 100 when in transit; or utilizing heat saved in the heat exchanger and reservoir 124 to enhance productivity of the SOEC 309 by augmenting the heat generated by the CSP 103 or by replacing the source heat during non-operation of the CSP 103. The foregoing list of functions enabled by SCADA operation control object tags for the embodiment of FIG. 3 is purely exemplary and any SCADA operation control tags describing any mode of action or process state for any system 103, 309, 314, 320, 125 of the embodiment represented in FIG. 3 remains within the scope and spirit of the present invention.

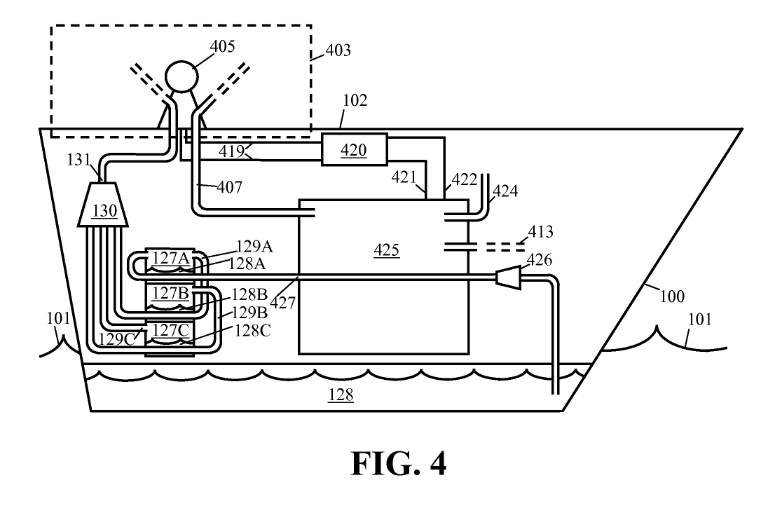

FIG. 4 presents an embodiment of the present invention that utilizes a Solid State Ammonia Synthesis (SSAS) 425 reactor for storage of energy as in hydrogen in molecules of liquid ammonia (NH₃) or for storage of ammonia as a feedstock for another industrial process such as fertilizer production. The present specification exemplifies Solid State Ammonia Synthesis SSAS 425, chosen for its purported highest efficiency of ammonia synthesis processes, and because it uniquely displaces the SOEC 109, 209, 309 of previous drawing figures because of its high temperature steam intake 407 operating at 550 degrees Celsius. Although FIG. 4 depicts Solid State Ammonia Synthesis SSAS 425, one understands that use of any other process to synthesize ammonia, such as Haber Bosch after obtaining hydrogen from electrolysis by any of the aforementioned means 109, 209, 309 depicted in the previous drawing figures, in an embodiment of mobile buoyant energy recovery systems 100 remains within the scope of the present invention. While illustrated in FIG. 4 as a single process, any configuration where SSAS 425 or Haber Bosch after electrolysis 109, 209, 309 proceeds in parallel with any other aforementioned function that fits between the high temperature high pressure steam path 407 starting at 550 to 800 degrees Celsius and returning heat 427 for the water purification process 127A, B, C at approximately 120 degrees Celsius on a mobile buoyant energy recovery system 100 remains within the scope and spirit of the present invention. Note ammonia synthesis from a mobile buoyant energy system 100 by processes such as SSAS 425, or electrolysis 109, 209, 309 followed by Haber Bosch, produces no carbon dioxide, as does present day industry's prevalent process of ammonia synthesis, Haber Bosch using hydrogen from methane steam reforming (MSR). Thus, the SCADA server side applications which access a Geographic Information System (GIS) also comprise a database recording amount of carbon by-product and calculating Levelized Cost of Energy (LCOE) reflecting a total cost analysis taking into consideration the amount of carbon by-product incurred, energy consumed, and commodity resource logistics and storage options in comparison to those availed by a modular mobile buoyant energy recovery system 100, and ammonia synthesis 425 and storage process costs into the path cost and total yield analysis.

A CSP 103 system corresponding to that of FIG. 1 or a CPV 203 system corresponding to that of FIG. 2 generates heat in the form of superheated steam immediately routed 407 through the mounting 405 of the solar power system 403 to the SSAS 425 of FIG. 4. As before one design feature which eliminates the conduit 407 by integrating ammonia synthesis 425 in proximity to, or coinciding with, or within the solar power system 403 remains within the scope and spirit of the present invention. From the previous paragraph, the reaction in which nitrogen and hydrogen combine to form ammonia occurs at 550 degrees Celsius and thus allows a solar power system 403 to comprise a CPV 203 operating at a cooler temperature compared to that in the embodiment including the SOEC 209, or a CSP 103 to include an SOEC 109 to produce hydrogen from the steam at the temperatures between 800 degrees Celsius and 550 degrees Celsius, before the ammonia synthesis 425. Ammonia synthesis 425, whether SSAS 425 or Haber Bosch after obtaining hydrogen from a SOEC 109, requires superheated steam 407 at 550 degrees Celsius, Air intake 424 from which to separate nitrogen in an air separation unit, and direct current electricity 421, 422. Either of the aforementioned ammonia synthesis 425 processes releases oxygen 413 as a by-product and thus may be combined with the oxygen from the center cavity 113 of the SOEC 109 and stored or vented to the environment 101, and, as in previous embodiments, accounted accordingly for as a yielded commodity addressed by a SCADA data object tag in a server database application. From either ammonia synthesis 425 process, surplus heat is exchanged within the reactor 425 to heat water 427 to approximately 120 degrees Celsius, en route to the distillation process, 127A, B, C, pumped 426 from the ballast 128.

The power regulation circuit 420 illustrated in FIG. 4 provides power to the reactor 425 through electrodes 421, 422, regulated from its source 419. The source 419 could be any of the aforementioned electricity sources including a CPV 203, a turbine 114, 314, or an SOEC 109 coupled with a hydrogen fuel cell. While not shown in FIG. 4, the power regulation circuit 420 may also comprise some means of energy storage, such as a battery, an ammonia or hydrogen internal combustion engine operatively coupled to an electrical generator, or an ammonia or hydrogen fuel cell attached to storage, so all electrical systems may remain functional regardless of the operation of the solar power system 403. One may assume all electrical systems on the mobile structure 100, such as motors for pumps or compressors or solenoids for control valves, navigation or propulsion, lighting, and communications, receive their power through the power regulation circuit 420. The power regulation circuit 420 of FIG. 4 also represents the SCADA control and communications microprocessor system, which communicates to a central server using data object tags describing temperature, heat, electrical power, and energy stored from the ammonia synthesis 425 and solar power system 403 and enables an operator to remotely track system efficiency and performance, and decide configuration, operation, or navigation of the mobile buoyant energy recovery system 100.

As one can see from the foregoing figures and their descriptions alluding to a multitude of possible configurations of design options for heat exchange, electricity generation, and commodity storage and delivery means previously disclosed herein, there exists a plurality of embodiments of mobile buoyant energy recovery structures 100 within the scope of the present invention. SCADA controlled and optimized configuration, operation, or navigation of one or a fleet of a modularized mobile buoyant energy recovery system 100 and its components 103, 203, 109, 209, 309, 114, 314, 124, 125, 425, 127, 128, and subparts thereof as Line Replaceable Units (LRU's) to produce any of a variety of commodities such as but not limited to hydrogen, oxygen, ammonia, lye, bleach, concentrated saline—sea salt, pure water, any mineral or compound electrochemically or thermo-chemically isolated from seawater, and deliver in and from an offshore environment 101; or substantially autonomous modular mobile buoyant structures 100 yielding energy or other energy-intensive commodities from the environment 101, based on heat and electrical cogeneration whose configuration, operation, or navigation is based on a SCADA computer network of servers informing its operator and clients or PLC's in the structures 100, exists as a fundamental departure from prior art. Another area of substantial novelty in the present invention exists as a SCADA system enables operators the ability to decide configuration, operation, and navigation of a modular, morphological natural resource exploitation structure 100 given server data including but not limited to: weather prediction, and weather pattern tracking; commodity prices and future prices at various geographic locations and currency exchange rates; component 103, 203, 109, 209, 309, 114, 314, 124, 125, 425, 127, 128 and LRU bill-of-material costs; component 103, 203, 109, 209, 309, 114, 314, 124, 125, 425, 127, 128 and LRU reliability data, maintenance costs and schedules, material safety data sheets; total carbon or toxic material by-product emitted and energy embodied and associated costs for the original manufacture, disposal, maintenance and operations of every component; and thus a database that definitively determines and enables at an operator's discretion, action based on decisions of a universal levelized cost of energy (LCOE) and commodities; all for various scale, for instance, mega or giga Watt structures 100, and based on yield analysis and performance models of any one of a plurality of modular structures 100 to determine least cost or highest yield path. The adaptability of the design and operation of an energy or energy-intensive commodity recovery system 100 facilitated by a SCADA system programmed to optimize resource allocation over vast domains 101 and to most economically and expeditiously respond to alleviate scarcity or emergency conditions for humanity remains the highest concept to which the present invention claims novel priority.

From the preceding description of the present invention, this specification manifests various techniques for use in implementing the concepts of the present invention without departing from its scope. Furthermore, while this specification describes the present invention with specific reference to certain embodiments, a person of ordinary skill in the art would recognize that one could make changes in form and detail without departing from the scope and the spirit of the invention. This specification presented embodiments in all respects as illustrative and not restrictive. All parties must understand that this specification does not limit the present invention to the previously described particular embodiments, but asserts the present invention's capability of many rearrangements, modifications, omissions, and substitutions without departing from its scope.

Thus, a solar cogeneration vessel has been described.

What is claimed is:

1. A mobile buoyant energy recovery system exploiting offshore solar heat and electrical power cogeneration comprising:
a first heat exchanger; wherein said first heat exchanger transfers heat energy from sunlight to a heat transfer fluid;
a second heat exchanger; wherein said second heat exchanger utilizes said heat transfer fluid in a process of storing energy, producing a commodity, or purifying water;
a source of electrical power;
a microprocessor system running process control, electrical, navigation, or operational systems for said mobile buoyant energy recovery system;
wherein said microprocessor system communicates to a supervisory control and data acquisition server which enables an operator to determine configuration, navigation, or operation of said mobile buoyant energy recovery system.

2. The mobile buoyant energy recovery system of claim 1 wherein said first heat exchanger comprises a solar thermal concentrator.

3. The mobile buoyant energy recovery system of claim 1 wherein said first heat exchanger comprises a solar photovoltaic cell; wherein said heat transfer fluid cools said solar photovoltaic cell.

4. The mobile buoyant energy recovery system of claim 1 wherein said source of electrical power comprises a wind turbine.

5. The mobile buoyant energy recovery system of claim 1 wherein said source of electrical power comprises a photovoltaic cell.

6. The mobile buoyant energy recovery system of claim 1 wherein said source of electrical power comprises a steam turbine.

7. The mobile buoyant energy recovery system of claim 1 wherein said second heat exchanger purifies water by transferring heat in a distillation process.

8. The mobile buoyant energy recovery system of claim 1 wherein said second heat exchanger stores heat for later use in an endothermic dehydrogenation reaction for a hydride energy storage system.

9. The mobile buoyant energy recovery system of claim 1 wherein said second heat exchanger stores heat for later use in a high temperature process when the first heat exchanger is non-operative.

10. The mobile buoyant energy recovery system of claim 1 wherein said supervisory control and data acquisition server enables an operator to determine configuration, navigation, or operation of said mobile buoyant energy recovery system based on a database of performance prediction models; path costs and yield analysis; component efficiency, energy density, maintenance, and reliability data; local commodity prices, future prices, and currency exchange rates; levelized cost of energy; or weather information.

11. The mobile buoyant energy recovery system of claim 1 wherein said microprocessor system of said mobile buoyant energy recovery system communicates to said supervisory control and data acquisition server to update a database; said updates provide data of: performance prediction models; path costs and yield analysis; component efficiency, energy density, maintenance, and reliability data; levelized cost of energy; or weather information; to optimize navigation and operation of said mobile buoyant energy recovery system.

12. A modular system configured to extract, store, or deliver energy or energy-intensive commodities from an offshore environment, said modular system comprising:
a supervisory control and data acquisition system server comprising a database providing information to determine configuration, navigation, or operation of said modular system;
one or a fleet of mobile buoyant structures; said mobile buoyant structures comprising:
solar heat and electrical power cogeneration components;
a microprocessor system running process control, electrical, navigation, or operational systems for said mobile buoyant structure;
wherein said microprocessor system communicates to said supervisory control and data acquisition system server.

13. The modular system of claim 12 wherein said solar heat and electrical power cogeneration components comprise:
a first heat exchanger; wherein said first heat exchanger transfers heat energy from sunlight to a heat transfer fluid;
a second heat exchanger; wherein said second heat exchanger utilizes said heat transfer fluid in a process of storing energy, producing a commodity, or purifying water;
a source of electrical power.

14. The modular system of claim 12 wherein said mobile buoyant structure extracts, stores, or delivers energy as in charged batteries or heat, hydrogen, oxygen, ammonia, lye, bleach, concentrated saline, sea salt, pure water, or any mineral or compound from said offshore environment according to said configuration of said modular system.

15. The modular system of claim 12 wherein said database of said supervisory control and data acquisition system server comprises: performance prediction models;
path costs and yield analysis; component bill-of-materials, manufacturing, operation, and disposal costs, material safety data sheets, toxicity, efficiency, energy density, maintenance cost and schedule, and reliability data; local commodity prices, future prices, and currency exchange rates; levelized cost of energy; or weather prediction and weather pattern tracking information.

16. The modular system of claim 14 wherein said configuration of said modular system is decided by an operator accessing a computer graphical user interface which communicates with said database of said supervisory control and data acquisition system server.

17. The modular system of claim 16 wherein said database of said supervisory control and data acquisition system server comprises: performance prediction models; path costs and yield analysis; component bill-of-materials, manufacturing, operation, and disposal costs, material safety data sheets, toxicity, efficiency, energy density, maintenance cost and schedule, and reliability data; local commodity prices, future prices, and currency exchange rates; levelized cost of energy; or weather prediction and weather pattern tracking information.

18. The modular system of claim 17 wherein said operator accessing a computer graphical user interface decides optimized autonomous operation and navigation of said modular system based on data from said database.

19. The modular system of claim 12 wherein said microprocessor system of said mobile buoyant structure communicates with said supervisory control and data acquisition system server to update said database; said updates provide data of:
performance prediction models; path costs and yield analysis; component efficiency, maintenance, and reliability data; levelized cost of energy; or weather prediction and weather pattern tracking information; to optimize autonomous operation and navigation of said mobile buoyant structures.

20. The modular system of claim 19 wherein said optimized autonomous operation and navigation of said mobile buoyant structures is decided by an operator accessing a computer graphical user interface which communicates with said updated database of said supervisory control and data acquisition system server.

21. The modular system of claim 12 wherein said microprocessor system of said mobile buoyant structure is a programmable logic controller.

22. The modular system of claim 12 wherein said mobile structure returns said extracted commodity to said offshore environment for purposes of environmental remediation.

23. The modular system of claim 22 wherein said database on said supervisory control and data acquisition system server accounts for said environmental remediation.

24. A supervisory control and data acquisition system for determining configuration, navigation, or operation of one or a fleet of modular mobile buoyant structures for recovering or delivering energy or energy-intensive commodities from offshore environments, said supervisory control and data acquisition system comprising:
a server comprising a database providing information to determine configuration, navigation, or operation of said modular mobile buoyant structures;
a microprocessor system running process control, electrical, navigation, or operational systems for said modular mobile buoyant structures;
wherein said modular mobile buoyant structures for recovering energy or energy-intensive commodities from offshore environments comprise solar heat and electrical power cogeneration components.

25. The supervisory control and data acquisition system of claim 24 wherein a graphical user interface displays options to an operator to determine configuration, navigation, or operation of said modular mobile buoyant structures.

26. The supervisory control and data acquisition system of claim 24 wherein said microprocessor system running process control, electrical, navigation, or operational systems for said modular mobile buoyant structures comprises a programmable logic controller adapted for supervisory control and data acquisition systems.

27. The supervisory control and data acquisition system of claim 24 wherein said database of said supervisory control and data acquisition system server comprises: performance prediction models for said modular mobile buoyant structures; path costs and yield analysis for said modular mobile buoyant structures; component bill-of-materials, manufacturing, operation, and disposal costs, material safety data sheets, toxicity, efficiency, energy density, maintenance cost and schedule, and reliability data for said modular mobile buoyant structures; local commodity prices, future prices, and currency exchange rates; levelized cost of energy; or weather prediction and weather pattern tracking information.

28. The supervisory control and data acquisition system of claim 24 wherein said modular mobile buoyant structures recover or deliver energy as in charged batteries or heat, hydrogen, oxygen, ammonia, lye, bleach, concentrated saline, sea salt, pure water, or any mineral or compound from said offshore environment according to said configuration of said modular mobile buoyant structures.

29. The supervisory control and data acquisition system of claim 24 wherein said microprocessor system of said modular mobile buoyant structures communicates with said supervisory control and data acquisition system server to update said database; said updates provide data of: performance prediction models of said modular mobile buoyant structures; path costs and yield analysis of said modular mobile buoyant structures; component efficiency, maintenance, and reliability data of said modular mobile buoyant structures; levelized cost of energy; or weather prediction and weather pattern tracking information; to optimize autonomous operation and navigation of said modular mobile buoyant structures.

30. The supervisory control and data acquisition system of claim 24 wherein said modular mobile buoyant structures for recovering energy or energy-intensive commodities from offshore environments comprise:
a first heat exchanger; wherein said first heat exchanger transfers heat energy from sunlight to a heat transfer fluid;
a second heat exchanger; wherein said second heat exchanger utilizes said heat transfer fluid in a process of storing energy, producing a commodity, or purifying water;
and, a source of electrical power.

31. The supervisory control and data acquisition system of claim 30 wherein said first heat exchanger comprises a solar thermal concentrator.

32. The supervisory control and data acquisition system of claim 30 wherein said first heat exchanger comprises a solar photovoltaic cell; wherein said heat transfer fluid cools said solar photovoltaic cell.

33. The supervisory control and data acquisition system of claim 32 wherein said source of electrical power comprises a photovoltaic cell.

34. The supervisory control and data acquisition system of claim 33 wherein said microprocessor system running process control, electrical, navigation, or operational systems for said modular mobile buoyant structures comprises solar cell maximum power point tracking control.

35. The supervisory control and data acquisition system of claim 30 wherein said source of electrical power comprises a steam turbine.

36. The supervisory control and data acquisition system of claim 30 wherein said source of electrical power comprises a wind turbine.

37. The supervisory control and data acquisition system of claim 36 wherein said microprocessor system running process control, electrical, navigation, or operational systems for said modular mobile buoyant structures comprises a function to adjust pitch of impeller blades of said wind turbine according to rotor rotation speed of said wind turbine.

38. The supervisory control and data acquisition system of claim 36 wherein said microprocessor system running process control, electrical, navigation, or operational systems for said modular mobile buoyant structures comprises a function to feather the impeller blades of said wind turbine when said modular mobile buoyant structures are in transit or in severe weather.

39. The supervisory control and data acquisition system of claim 24 wherein said microprocessor system running process control, electrical, navigation, or operational systems for said modular mobile buoyant structures comprises a function to moor or set heading of said modular mobile buoyant structures, said function allowing simple one axis solar tracking of said solar heat components.

40. The supervisory control and data acquisition system of claim 30 wherein said microprocessor system running process control, electrical, navigation, or operational systems for said modular mobile buoyant structures comprises control of heat saved in said second heat exchanger to enhance productivity of said recovering or delivering energy or energy-intensive commodities from said offshore environments.
